(19) United States
(12) Patent Application Publication
(10) Pub. No.: US 2024/0111828 A1
(43) Pub. Date: Apr. 4, 2024

(54) IN MEMORY COMPUTING PROCESSOR AND METHOD THEREOF WITH DIRECTION-BASED PROCESSING

(71) Applicant: SAMSUNG ELECTRONICS CO., LTD., Suwon-si (KR)

(72) Inventors: Dohun Kim, Suwon-si (KR); SOON-WAN KWON, Suwon-si (KR)

(73) Assignee: SAMSUNG ELECTRONICS CO., LTD., Suwon-si (KR)

(21) Appl. No.: 18/108,718

(22) Filed: Feb. 13, 2023

(30) Foreign Application Priority Data
Sep. 29, 2022 (KR) 10-2022-0124518

(51) Int. Cl. G06F 17/16; G06N 3/0464

(52) U.S. Cl. CPC G06F 17/16; G06N 3/0464

(57) ABSTRACT

Disclosed is an in memory computing (IMC) processor. An in memory computing (IMC) processor includes a static random access memory (SRAM) IMC device including type 1 IMC macros in which a direction of writing data therein is the same as an operation direction of performing a multiply and accumulate (MAC) operation in the type 1 IMC macros, and type 2 IMC macros in which a direction of writing data therein is different from the operation direction in the type 1 IMC macros, and the SRAM IMC device is configured to use the type 1 IMC macros and the type 2 IMC macros to perform a multiply and accumulation (MAC) operation between an input feature map and a weight, and a shift accumulator configured to perform a shift operation on an output of the SRAM IMC device and accumulate a result of the shift operation.

### CROSS-REFERENCE TO RELATED APPLICATIONS

This application claims the benefit under 35 USC § 119(a) of Korean Patent Application No. 10-2022-0124518, filed on Sep. 29, 2022, in the Korean Intellectual Property Office, the entire disclosure of which is incorporated herein by reference for all purposes.

### BACKGROUND

### 1. Field

The following disclosure relates to an in memory computing (IMC) processor and an operating method of the IMC processor.

### 2. Description of Related Art

The utilization of deep neural networks (DNNs) is leading to advances in the industrial application of artificial intelligence (AI). A convolutional neural network (CNN), one type of DNN, is widely used in various application fields, such as, for example, image and signal processing, object recognition, computer vision, and the like. A device that implements or executes a CNN may be configured to perform a multiple and accumulation (MAC) operation that efficiently repeats multiplication and addition between a considerably large number of matrices. When a CNN is executed by using general-purpose processors (a Von Neumann architecture), although the MAC operation requires a considerable amount of computation, it is not a complex operation. A MAC operation, which calculates an inner product of two vectors of respective matrices and accumulates and sums the values of each vector inner product, may be performed through in memory computing (IMC).

The above description has been possessed or acquired by the inventor(s) in the course of conceiving the present disclosure and is not necessarily an art publicly known before the present application is filed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an in memory computing (IMC) processor includes a static random access memory (SRAM) IMC device including type 1 IMC macros in which a direction of writing data therein is the same as an operation direction of performing a multiply and accumulate (MAC) operation in the type 1 IMC macros, and type 2 IMC macros in which a direction of writing data therein is different from the operation direction in the type 1 IMC macros, and the SRAM IMC device is configured to use the type 1 IMC macros and the type 2 IMC macros to perform a multiply and accumulation (MAC) operation between an input feature map and a weight, and a shift accumulator configured to perform a shift operation on an output of the SRAM IMC device and accumulate a result of the shift operation.

An output end of a type 1 IMC macro may be connected, via the shift accumulator, with an input end of a type 2 IMC macro, and an output end of the type 2 IMC macro may be connected with an input end of the type 1 IMC macro.

Each of the type 2 IMC macros may be configured to perform an accumulation operation according to the operation direction of the type 2 IMC macros by receiving one bit according to the direction of the writing of the type 2 IMC macros.

Each of the type 2 IMC macros may be configured to perform their MAC operation by receiving bits according to the direction of writing of the type 2 IMC macros.

The SRAM IMC device may be configured to perform the MAC operation between the input feature map and the weight by storing the input feature map in a type 1 IMC macro while the weight may be streamed into the type 1 IMC macro.

The shift accumulator may be configured to perform a first-direction partial sum operation by performing a shift operation on a MAC operation result of each of the type 1 IMC macros and by accumulating the result of the shift operation.

The SRAM IMC device may be further configured to accumulate a result of the first-direction partial sum operation using the type 2 IMC macros.

The shift accumulator may include a buffer, where the buffer may include a first region storing or accumulating a MAC operation result corresponding to the type 1 IMC macros, and a second region for preventing data loss arising from the shift operation, and where a size of the first region and a size of the second region may be determined based on a size of the type 1 IMC macros.

The shift accumulator may be configured to be capable of performing the shift operation on a MAC operation result in a left direction and in a right direction, and may be configured to accumulate the result of the shift operation.

The MAC operation may include a linear operation or a convolution operation.

The IMC processor may be integrated into either a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, or a medical device.

The shift accumulator may be configured to perform an accumulation operation according to the operation direction, with output vectors corresponding to the type 1 IMC macros, respectively, streamed.

In one general aspect, a static random access memory (SRAM) in memory computing (IMC) device includes type 1 IMC macros, in which a write direction of data may be the same as an operation direction, and type 2 IMC macros, in which a write direction of data is different from the operation direction, and the SRAM IMC device is configured to perform a multiply and accumulation (MAC) operation between an input feature map and a weight.

Either the input feature map or the weight may be stored in the IMC macros, and whichever of the two is not written may be instead streamed to the IMC macros.

An input streamer may be configured to delay a weight map corresponding to each of the type 1 IMC macros by as much as a unit cycle and stream the delayed weight map to an applicable one of the type 1 IMC macros.

The type 2 IMC macros may be configured to perform an accumulation operation according to the operation direction, with output vectors corresponding to the type 1 IMC macros, respectively, streamed.

In one general aspect, a method of operating an in memory computing (IMC) processor includes performing a multiply and accumulation (MAC) operation between an input feature map and a weight in any one of type 1 IMC macros of the IMC processor, in which a write direction of data is the same as an operation direction of the MAC operation, performing a first-direction partial sum operation by performing a shift operation on a MAC operation result of each of the type 1 IMC macros and accumulating a result of the shift operation, and accumulating a result of the first-direction partial sum operation, using type 2 IMC macros of the IMC processor, in which the write direction of the data is different from a direction of the operation result.

A non-transitory computer-readable storage medium may store instructions that, when executed by a processor, cause the processor to perform the operating method.

Other features and aspects will be apparent from the following detailed description, the drawings, and the claims.

### BRIEF DESCRIPTION OF THE DRAWINGS

FIG. 1 illustrates an example of a relationship between an in memory computing (IMC) macro and an operation performed by a neural network, according to one or more embodiments.

FIG. 2A illustrates an example of data flow in which a convolution operation is performed by an IMC processor, according to one or more embodiments.

FIG. 2B illustrates an example of reusing input data in a convolution operation, according to one or more embodiments.

FIG. 3 illustrates an example of using an output of a previous IMC macro as-is for a next IMC macro, according to one or more embodiments.

FIG. 4 illustrates an example of a hardware structure of an IMC processor, according to one or more embodiments.

FIG. 5A illustrates examples structure of types of IMC macros, according to one or more embodiments.

FIG. 5B illustrates an example structure of an IMC macro type, according to one or more embodiments.

FIGS. 6A to 6C illustrate an example of a method of performing a linear operation between input data and a weight, according to one or more embodiments.

FIG. 7 illustrates an example of a method of performing a convolution operation, according to one or more embodiments.

FIG. 8 illustrates an example of a method of performing a convolution operation, according to one or more embodiments.

FIG. 9 illustrates an example method of performing a MAC operation between an input feature map and a weight, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Examples described herein may be implemented as various types of products, such as, for example, a personal computer (PC), a laptop computer, a tablet computer, a smartphone, a television (TV), a smart home appliance, an intelligent vehicle, a kiosk, and a wearable device. Hereinafter, examples will be described in detail with reference to the accompanying drawings. In the drawings, like reference numerals are used for like elements.

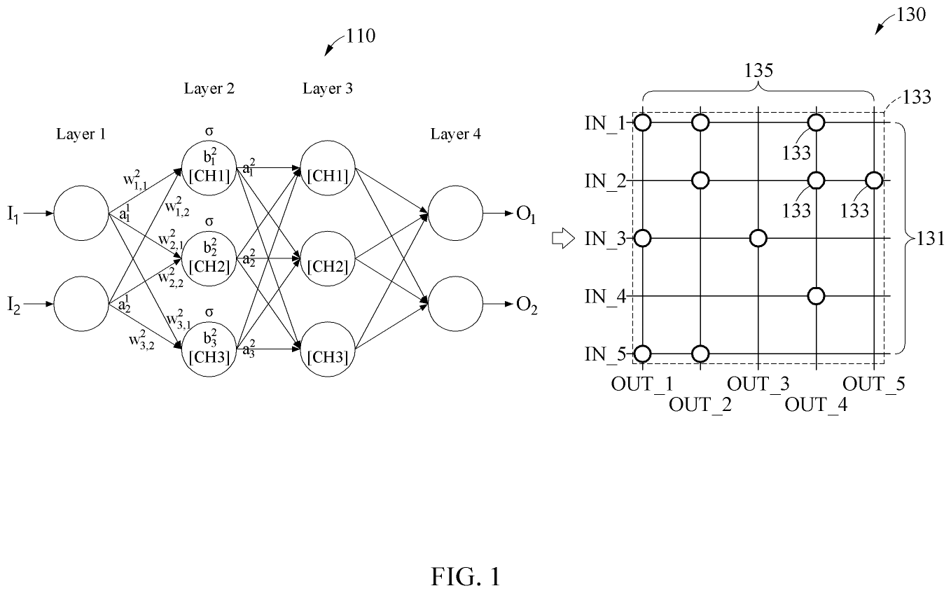

FIG. 1 illustrates an example of a relationship between an in memory computing (IMC) macro and an operation performed by a neural network, according to one or more embodiments. FIG. 1 shows a neural network 110 and a memory array 130 of an IMC macro corresponding (conceptually) to the neural network 110.

IMC memory devices implement a type of computing architecture that allows an operation to be performed directly in a memory in which data is stored, to overcome the performance limits and reduce the power consumption that results from the frequent data movement between the memory and an operation unit (e.g., a processor) occurring in the von Neumann architecture. IMC devices may be classified into analog IMC and digital IMC according to the domain in which an operation is to be performed. An analog IMC device may perform an operation in an analog domain, such as, for example, current, charge, time, or the like. A digital IMC device may perform an operation in a digital domain using a logic circuit.

IMC may accelerate a matrix operation such as a multiply and accumulate (MAC) operation that efficiently performs an addition of a number of multiplications for learning/training and inferencing of neural network models, for example. In this case, when the memory IMC includes bit cells in an IMC macro, and the bit cells store data of the neural network 110 (e.g., weights), an operation of multiplication and summation for the neural network 110 may be performed through the IMC macro of the memory array 130.

The IMC macro may perform the multiplication and summation of a MAC operation by using computing functionality of the memory array 130 provided by the bit cells and operators of the memory array 130, thereby enabling machine learning/inferencing of the neural network 110.

For example, the neural network 110 may be a deep neural network (DNN) including an input layer (Layer 1), two hidden layers (Layer 2 and Layer 3), and an output layer (Layer 4). Examples are not limited thereto. The neural network 110 may perform an operation based on received input data (e.g., I₁ and I₂) and generate output data (e.g., O₁ and O₂) based on a result of performing the operation.

The neural network 110 may be a DNN or n-layer neural network including two or more hidden layers, as described above. When the neural network 110 is implemented with a DNN architecture, the neural network 110 includes more layers capable of processing valid information. Thus, the neural network 110 may process more complex data sets than a neural network having a single layer. Although FIG. 1 illustrates the neural network 110 including four layers, examples are not limited thereto. The neural network 110 may include fewer or more layers or may include fewer or more channels. The neural network 110 may include layers in various architectures different from that shown in FIG. 1.

Each of the layers included in the neural network 110 may include links or connections between nodes. The connections may correspond to a nodes, sometimes referred to as neurons, processing elements (PEs), units, or other similar terms.

The connections included in each of the layers of the neural network 110 may be connections between nodes to process data. For example, one node may perform an operation by receiving data from other nodes (via respective connections) and output an operation result to other channels.

An input and an output of each of the nodes may be referred to as an input activation and an output activation, respectively. ‘Activation’ may be an output of one node and, at the same time, may be an input of nodes included in the next layer. In addition, each of the nodes may determine its activation based on weights and activations received from nodes in a previous layer. A weight is a parameter used to calculate an output activation in each node and may be a value assigned to a connection relationship between nodes.

Each of the nodes may be processed by a computational unit (CU) or PE that receives an input and outputs an output activation, and the input and the output of each of the channels may be mapped.

For example, activation may be performed in accordance with Equation 1 below, where a denotes an activation function, wⱼₖⁱ denotes a weight from a k^{th} channel included in an (i−1)^{th} layer to j^{th} channel included in an j^{th} layer, bⱼⁱ denotes a bias of the j^{th} channel included in the i^{th} layer, aⱼⁱ denotes an activation of the j^{th} channel of the i^{th} layer, then the activation aⱼⁱ may be calculated by using Equation 1.

$${a}_{j}^{i} = σ ( {\sum }_{k} ( {w}_{jk}^{i} \times {a}_{k}^{i - 1} ) + {b}_{j}^{i} ) \qquad Equation 1$$

As shown in FIG. 1, an activation of a first channel (CH1) of the second layer (Layer 2) may be expressed as a₁². In addition, under the assumption that k is 2, according to Equation 1, a₁² may have a value of a₁²=(w_{1,1}²×a₁¹+w_{1,2}²×a₂¹+b₁²). The activation function a may be, for example, a rectified linear unit (ReLU), a sigmoid, a hyperbolic tangent (tanh), and Maxout. However, examples are not limited thereto.

An input or an output between nodes in the neural network 110 may be expressed as a weighted sum between an input i and a weight w. The weighted sum involves multiplication operations and iterative addition operations between inputs and weights and may also be referred to as a “MAC operation”. Since a MAC operation is performed using a memory having a computing function, a circuit for performing a MAC operation may be referred to as an “IMC circuit”.

The neural network 110 may exchange numerous data sets between mutually connected nodes and may perform operation process through the layers of the neural network 110. In this operation process, numerous MAC operations are performed, and a number of memory access operations may be performed together to load activations and weights that are operands for the MAC operations at appropriate points in time.

According to an example, an IMC processor may include a MAC macro in which the memory array 130 is configured in a crossbar array structure for addressing elements of the memory array 130. The memory array 130 may include word lines 131, bit cells 133, and bit lines 135. The word lines 131 may be used to receive input data of the neural network 110. For example, when there are N word lines 131, a value corresponding to input data of the neural network 110 may be applied to the N word lines (at an input layer, the input data may be data inputted to the neural network 110, and at any later layer the input data may be a result of previous processing of the input data by the neural network 110). The word lines 131 may intersect with the bit lines 135. For example, when there M bit lines 135, the bit lines 135 and the word lines 131 may intersect at N×M intersection points.

Furthermore, the bit cells 133 may be at the intersecting points of the word lines 131 and the bit lines 135. Each of the bit cells 133 may be implemented as, for example, volatile memory (e.g., static random access memory (SRAM)) to store weights. However, examples are not limited thereto. For example, each of the bit cells 133 may be implemented as non-volatile memory such as resistive random-access memory (ReRAM), eFlash, or the like.

The word lines 131 may be referred to as “row lines” in that they correspond to rows that are arranged in a horizontal direction in the memory array 130. The bit lines 135 may be referred to as “column lines” in that they correspond to columns that are arranged in a vertical direction in the memory array 130. Hereinafter, the terms “word line(s)” and “row line(s)” may be used interchangeably. Furthermore, the terms “bit line(s)” and “column line(s)” may be used interchangeably. The terms “horizontal” and “vertical” are for mutual reference and do not imply a specific orientation with respect to a chip or device.

The word lines 131 may sequentially receive values corresponding to the input data of the neural network 110 (e.g., original input data at an input layer, intermediate data at an intermediate layer, etc.). In this case, the input data may be, for example, input data included in an input feature map or weight values stored in a weight map.

For example, an input signal IN_1 for an IMC device may be “1” or “high” when the input signal IN_1 is applied to a first word line of the memory array 130 in a first cycle corresponding to the input signal IN_1. An input signal IN_2 for the IMC device may be “0” or “low” when the input signal IN_2 is applied to a second word line of the memory array 130 in a second cycle corresponding to the input signal IN_2. And so forth.

It might be necessary to sequentially input the input signals for the IMC device to the word lines 131 to prevent two or more input signals from colliding on the same bit line. If no collision occurs on the same bit line, the IMC device may simultaneously input two or more input signals to the word lines 131.

Each of the bit cells 133 of the memory array 130 may be disposed at an intersecting point of a word line and a bit line corresponding to the bit cell. Each of the bit cells 133 may store data corresponding to 1 bit. Each of the bit cells 133 may store weight data of a weight map or input data of an input feature map. That is, with respect to two operands of a MAC operation performed on data in the bit cells 133, the bit cells may store either of the operands (e.g., weight data, or input data).

For example, when a weight corresponding to a bit cell (i, j) is 1, the bit cell (i, j) disposed at an intersecting point of a corresponding word line i and a corresponding bit line j may transmit, to the corresponding bit line, an input signal which is input to the corresponding word line. Alternatively, if a weight corresponding to a bit cell (i+1, j+1) is 0, an input signal may not be transmitted to a corresponding bit line when the input signal is applied to a corresponding word line. In other words, the values of the bit cells may control the transmission of word lines onto bit lines.

In the example of FIG. 1, a weight corresponding to a bit cell (1, 1) corresponding to a first word line and a first bit line is 1; the bit cell is disposed at an intersecting point of the first word line and the first bit line. In this example, the input signal IN_1 input to the first word line may be transferred to the first bit line because of the value 1 in the bit cell.

Alternatively, since the weight in the bit cell (1, 3) (corresponding to the first word line and the third bit line) is 0, the bit cell may prevent the input signal IN_1 input to the first word line from being transmitted to the third bit line.

The bit cells 133 may also be referred to as “memory cells”. The bit cells 133 may include, for example, any one or any combination of a diode, a transistor (e.g., a metal-oxide-semiconductor field-effect transistor (MOSFET)), a SRAM bit cell, and a resistive memory. However, examples are not necessarily limited thereto. Hereinafter, a case of the bit cells 133 being SRAM bit cells will be described as an example. However, examples are not limited thereto.

The bit lines 135 may intersect with the word lines 131, and each of the bit lines 135 may output a value received from a corresponding input line through a corresponding bit cell.

Among the bit cells 133, bit cells disposed along the same word line may receive the same input signal and bit cells disposed along the same bit line may transmit the same output signal.

Considering the bit cells 133 disposed in the memory array 130 illustrated as an example in FIG. 1, the IMC device may perform a MAC operation as in Equation 2.

$$[ \begin{matrix}OUT\_ 1 \\ OUT\_ 2 \\ OUT\_ 3 \\ OUT\_ 4 \\ OUT\_ 5\end{matrix} ] = [ \begin{matrix}1 & 0 & 1 & 0 & 1 \\ 1 & 1 & 0 & 0 & 1 \\ 0 & 0 & 1 & 0 & 0 \\ 1 & 1 & 0 & 1 & 0 \\ 0 & 1 & 0 & 0 & 0\end{matrix} ] [ \begin{matrix}IN\_ 1 \\ IN\_ 2 \\ IN\_ 3 \\ IN\_ 4 \\ IN\_ 5\end{matrix} ] \qquad Equation 2$$

Bitwise multiplication operations may be performed and accumulated by bit cells included in the memory array 130 of the IMC macro, whereby a MAC operator or an AI accelerator may be implemented.

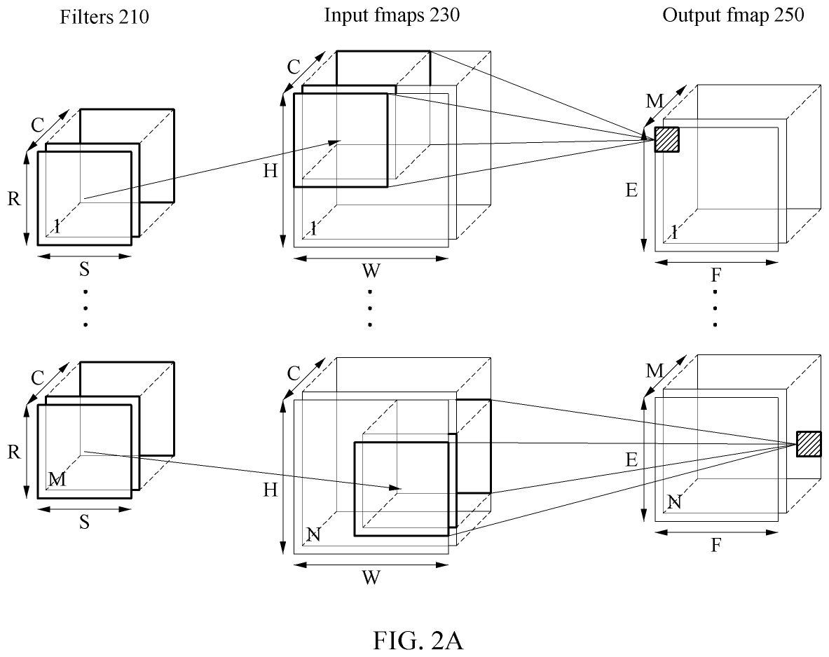

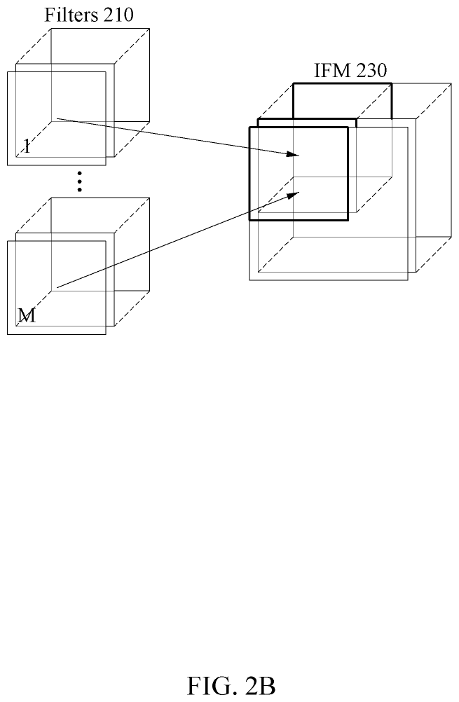

FIG. 2A illustrates an example of data flow when a convolution operation is performed by an IMC processor, according to one or more embodiments. FIG. 2B illustrates an example of reusing input data in a convolution operation, according to one or more embodiments.

Referring to FIG. 2A, filters 210 for a convolution operation, input feature maps (IFMs) 230, and output feature maps (OFMs) 250 are shown. The term “filter” may also be referred to as “weight map”. Hereinafter, the terms “filter” and “weight map” may be used interchangeably.

In FIG. 2A, R and S denote the height and the weight of each of the 2D filters 210. M denotes the number of three-dimensional (3D) filters 210. Furthermore, C denotes the number of input channels of a 2D IFM 230, and H and W denote the height and the width of the 2D IFM 230. In addition, E and F may denote the height and the weight of a 2D OFM 250, respectively.

For example, a convolutional neural network (CNN) may include several convolutional layers. Each of the convolutional layers may generate a continuous, high-level abstracted value including unique information of input data. In this case, the abstracted value corresponding to the input data may be referred to as an “IFM”.

When there are multiple feature maps or filters, each of the feature maps or filters may be called a “channel”. In FIG. 2A, the number of channels of the filters 210 is C and the number of channels of the IFMs 230 is also C. The number of channels in the OFMs is M. In FIG. 2A, N OFMs 250 may be generated by a convolution operation between the M filters 210 and the N IFMs 230.

The convolution operation may be performed by shifting the filters 210 (which have a predetermined size R×S) by a pixel or stride over the IFMs 230. Since the filters 210 and the IFMs 230 should have one-to-one correspondence according to the definition of convolution, the number of filters 210 and the number of channels of the IFMs 230 may be the same, i.e., C. The number of filters 210 and the number of channels of the OFMs 250 may also be the same, i.e., M. The number of filters 210 and the number of channels of the OFMs 250 may also be the same, i.e., M, because OFMs (by as many as the number of IFMs) may be generated per one channel when a convolution operation between the IFMs 230 and any one filter is performed.

The overall convolution operation may involve reading data from a memory device (e.g., dynamic random-access memory (DRAM)) outside the processor and storing the data into IMC macros; MAC operation results of the IMC macros may be stored in a buffer or a register. In this case, retrieving data from the external memory device (e.g., DRAM) may time and power intensive. Accordingly, it may be beneficial for the data retrieved from the external memory device to be reused, as possible, to reduce time and power consumption.

Generally, there are three types of data reuse, for example, convolutional reuse, weight data reuse (i.e., weight stationary), and/or input data reuse (i.e., input stationary), depending on which data is reused. The convolutional reuse type may reuse input data of both IFMs and weight data of weight maps. In implementations of convolutional reuse type, the weight maps may be reused by as many times as the number of OFMs, and the IFMs may be reused by as many times as the number of weight maps.

The weight data reuse type may also be referred to as a weight stationary dataflow, in that weight data of weight maps are fixed and reused (e.g., in an IMC macro). According to the weight data type of reuse, the weight data of the weight maps may be reused by as many times as the number of batches of the IFMs.

The input data reuse type may also be referred to as an input stationary dataflow, in that input data of IFMs are fixed and reused (e.g., in an IMC macro). According to the input data type of reuse, the input data of the IFMs may be reused as many times as the number of channels of the weight maps. An example of reusing input data is described in detail with reference to FIG. 2B.

FIG. 2B shows an example of reusing input data of one of the IFMs 230 as many times as the number of (e.g., M) channels of the filters 210 is shown.

For example, when input data of an IFM 230 is reused, the input data of the IFM 230 may be previously stored in a memory array of an IMC macro and used in a previous operation thereof. In this case, as the data (weight data) stored in the filters 210 is applied to the memory array (to the intermediate data therein), a convolution operation may be performed in bit cells of the memory array.

The convolution operation may be performed in a manner that the filters 210 perform an operation by shifting over data of any one IFM stored in the memory array by one bit or one stride. The stride may correspond to the number of bytes from one word line to a next word line of the bit cells of the memory array.

A partial sum that is a result of a convolution operation may be stored in bit cells (e.g., of an accumulation buffer/register) of the corresponding memory array that performs the convolution operation. The accumulation of the partial sum may be maintained in each accumulation bit cell until the final sum of the convolution operation reaches the OFM 250, thereby reducing the number of operations of reading and/or writing the partial sum.

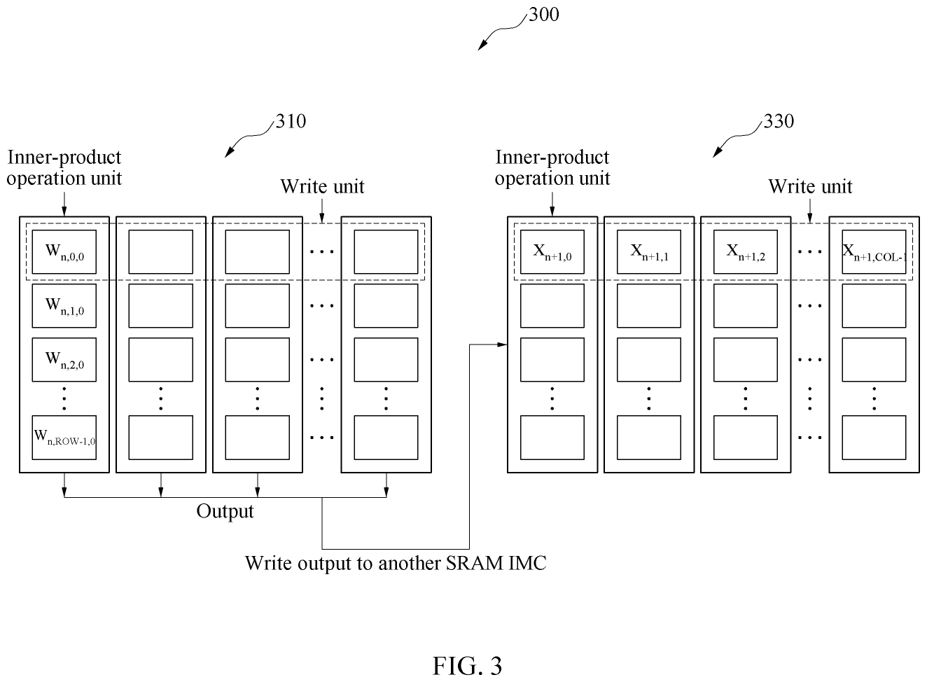

FIG. 3 illustrates an example of using an output of a previous IMC macro for a next IMC macro as it is, in an IMC macro having a general structure. FIG. 3 shows an example 300 of writing outputs of bit cells of a first IMC macro 310 to a second IMC macro 330 (for storage therein) in an IMC macro having a general structure.

IMC technology may generally use a structure that obtains a calculated output by applying data of an IFM to a memory in which weights are stored in advance (and possibly reused) and which is capable of performing computations. That is, many IMC-based AI processors may use a weight stationary dataflow.

For example, when an SRAM IMC macro is used, weight data may be read from a separate storage (e.g., a main system memory) and written to the SRAM IMC macro at each power-on point in time since SRAM is a volatile memory.

As shown in FIG. 3, the result of the convolution operation may be stored in the memory array of the first IMC macro 310 and then written to the second IMC macro 330 and used as it is. In this case, the unit of reading/writing the operation result stored in the memory array of the first IMC macro 310 from/to the memory array of the second IMC macro 330 may be in a row direction. Conversely, the unit of performing an operation (e.g., an inner-product operation) between the data stored in the memory array of the second IMC macro 330 and retrieved data may be in a column direction. As shown in FIG. 3, when the direction in which data is read/written from/to the memory array does not match the direction in which the operation is performed, it may not be easy to perform an operation between IMC macros not using weight data but a feature map which is an intermediate output of the convolution operation as it is.

That is, when the direction in which data is read/written from/to the memory array does not match the direction in which the operation is performed, a process of storing a feature map in a buffer and reading the buffer may need to be added since the feature map may not be directly written in the second IMC macro 330. In other words, an extra write and read may be needed to, for example, transpose the data. Such an additional process may increase processing time (add cycles to the operation), use chip/circuit area, and may increase data movement.

As described further below, in some embodiments an IMC processor may have and use two different types of IMC macros to when storing an output of a previous IMC macro into a next IMC macro, which may obviate the above-mentioned additional movement of data movement into and out of a buffer. Furthermore, the IMC processor according to an example may not only perform a weight stationary method of storing and computing a weight in the IMC macro but may also store and compute input data in the IMC macro.

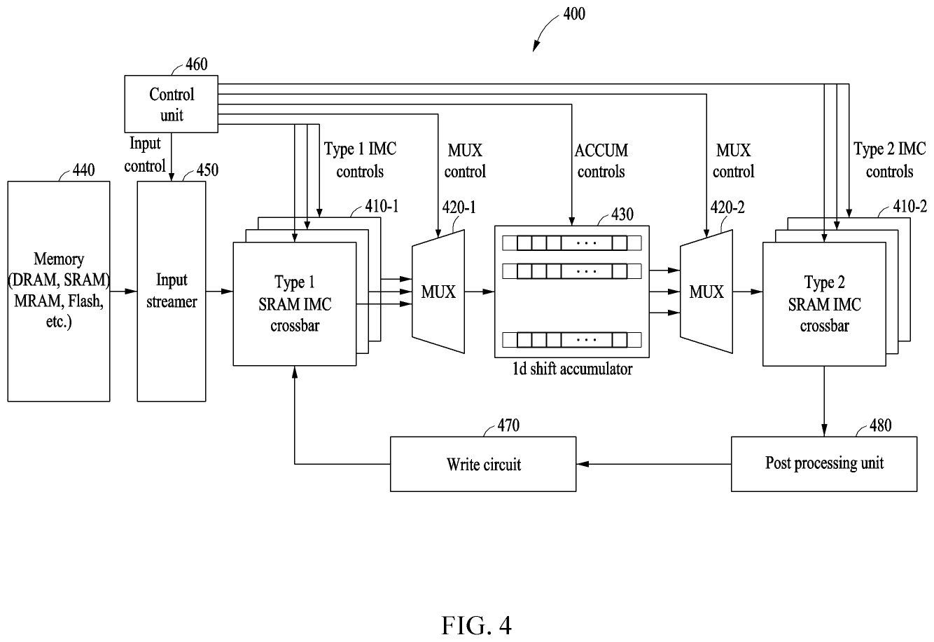

FIG. 4 illustrates an example hardware structure of an IMC processor, according to one or more embodiments. Referring to FIG. 4, an IMC processor 400 may include an SRAM IMC device, a first multiplexer (MUX) 420-1, a shift accumulator 430, a second MUX 420-2, memory devices 440, an input streamer 450, a control unit 460, a read write (RW) circuit 470, and a post processor block 480.

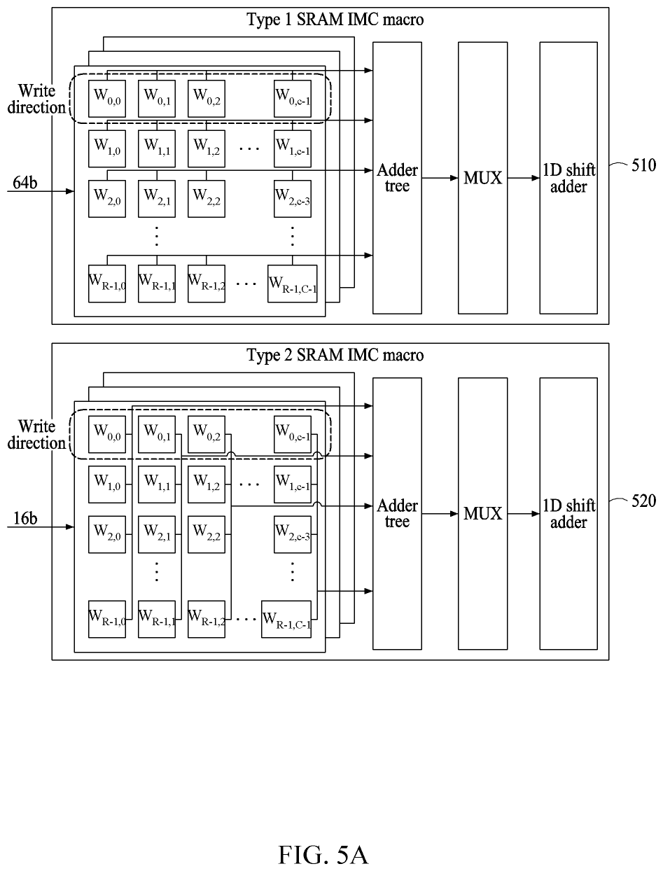

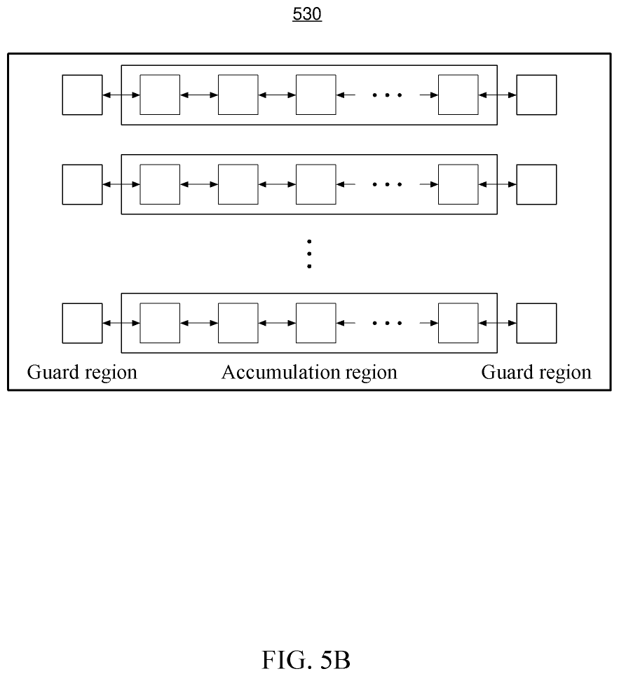

The SRAM IMC device may include a IMC macros. The IMC macros may be, for example, SRAM IMC macros. However, examples are not limited thereto. In each of the IMC macros, a write/read direction may be the same as or different from an operation direction. Each of the IMC macros 410 may have a form in which memory banks of multiple memory arrays (e.g., memory arrays 510 of FIG. 5) share a single digital operator (e.g., a digital operator 530 shown in FIG. 5). The multiple memory arrays may have, for example, a crossbar array structure. However, examples are not limited thereto.

The SRAM IMC macros may include type 1 IMC macros 410-1 and type 2 IMC macros 410-2. The type 1 IMC macros 410-1 may be IMC macros in which a write direction of data is the same as an operation direction of the data, and the type 2 IMC macros 410-2 may be IMC macros, in which the write direction of data is different from the operation direction of data. The structures of the type 1 IMC macros 410-1 and the type 2 IMC macros 410-2 are described with reference to FIG. 5.

When an input feature map and a weight (weight map) are operands of a MAC operation, one of the two may be already stored in the SRAM IMC device, and the other of the two may be streamed to the SRAM IMC device, so that the MAC operation between the operands (input feature map and the weight) may be performed. The MAC operation may be for a linear operation or a convolution operation. However, examples are not limited thereto.

All pieces of data may be expressed, for example, as a digital logical value of 0 or 1 and computed upon by the SRAM IMC device. Furthermore, input data, weight data, and output data in the SRAM IMC device may have a binary format.

The type 1 IMC macros 410-1 and the type 2 IMC macros 410-2 may share the shift accumulator 430. The IMC processor 400 may be able to perform a larger inner product operation by sharing the shift accumulator 430 between two IMC macros acting in concert, compared to the size of an inner product that can be performed by only one IMC macro acting alone.

The first MUX 420-1 may selectively transmit outputs of memory arrays of the type 1 IMC macros 410-1 to the shift accumulator 430, according to a control signal from the control unit 460. In other words, the first MUX 420-1 can be controlled to transmit outputs of specific memory arrays of the type 1 IMC macros 410-1.

The shift accumulator 430 may receive the outputs of the type 1 IMC macros 410-1 and perform a shift operation and accumulation on the outputs. The shift accumulator 430 may perform a shift operation on a MAC operation result of each of the type 1 IMC macros 410-1 and accumulate results of the shift operation, thus performing a first-direction partial sum. For example, the shift accumulator 430 may store an accumulation result in a buffer and/or an output register. However, examples are not necessarily limited thereto.

The memory devices 440 may store weight data of weight maps corresponding to both the type 1 IMC macros 410-1 and the type 2 IMC macros 410-2. The memory devices 440 may be non-volatile, for example, flash memory, magnetic random-access memory (MRAM), phase-change RAM (PRAM), and/or resistive RAM (RRAM). However, examples are not limited thereto.

The input streamer 450 may delay, for as much as a unit cycle, pieces of input data corresponding to the type 1 IMC macros 410-1 and the type 2 IMC macros 410-2, respectively, or weight data of the weight map, and stream them to an applicable IMC macro. Although not shown, the input streamer 450 may also have a connection (e.g., word lines) to the type 2 IMC macros 410-2.

The input streamer 450 may read, from the memory devices 440, weight data of the weight map or input data corresponding to one or more IMC macros capable of performing a simultaneous operation among the type 1 IMC macros 410-1 and the type 2 IMC macros 410-2. For example, the input streamer 450 may read the weight data of the weight maps stored in the memory devices 440 or may read the weight data from the weight map stored in a weight buffer.

The input streamer 450 may stream, to an applicable IMC macro, the weight data read at a point in time delayed for the unit cycle, for each of the one or more IMC macros. In other words, units of the read data may be sequentially passed to the applicable IMC macros.

The control unit 460 may generate and transmit control signals for the operation of the components of the IMC processor 400, according to clock signals. The control unit 460 may, for example, generate or transmit a control signal for the type 1 IMC macros 410-1, the type 2 IMC macros 410-2, the first MUX 420-1, the second MUX 420-2, the shift accumulator 430, and the input streamer 450.

The RW circuit 470 may write data to the type 1 IMC macros 410-1 and the type 2 IMC macros 410-2 or read data stored in the type 1 IMC macros 410-1 and the type 2 IMC macros 410-2. Although in FIG. 4 arrows indicate a data direction of data flowing from the type 2 IMC macros 410-2 to the type 1 IMC macros 410-2, data may flow in both directions. The RW circuit 470 may read and write data of one or more bit cells included in a memory array of the type 1 IMC macros 410-1 and the type 2 IMC macros 410-2, respectively. The data of one or more bit cells may include, for example, an input data value multiplied by weight data. For example, the RW circuit 470 may access the bit cells of the memory array through bit lines (e.g., RBL and RBLB) of the memory array of the type 1 IMC macros 410-1 and the type 2 IMC macros 410-2. When the memory array includes bit cells, the RW circuit 470 may access a bit cell connected to an activated word line among word lines RWL. The RW circuit 470 may write (store) data to the accessed bit cell or read data stored in the bit cell.

The post processor block 480 may correspond to a vector processor or a hardware (HW) accelerator that performs operations other than vector-matrix multiplication (VMM). For example, the post processor block 480 may perform element-wise multiplication, element-wise addition, batch normalization, non-linear function, and/or pooling on an operation result of VMM, that is, an operation result for different filters. However, examples are not limited thereto. The post processor block 480 may correspond to a separate digital logic capable of performing all such post processing operations.

The IMC processor 400 may be integrated into, for example, a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, a medical device, and so forth.

FIG. 5A illustrates example structure of types of IMC macros, according to one or more embodiments.

Referring to FIG. 5, an SRAM IMC device according to an example may include a type 1 IMC macro 510 and a type 2 IMC macro 520.

Hereinafter, the size of an IMC macro may be expressed as a row×column (ROW×COL). It is assumed that the size of the type 1 IMC macro 510 is 64×64 and the size of the type 2 IMC macro 520 is 16×64, but examples are not limited thereto.

Hereinafter, an example of input data being 8 bits long and weight data being 8 bits long is assumed. However, examples are not limited thereto. The input data and the weight data may be, for example, 4 bits, 16 bits, or 32 bits long.

In the type 1 IMC macro 510, a write/read direction may be the same as an operation direction. The type 1 IMC macro 510 may have a form in which memory banks of multiple memory arrays share a single digital operator. The type 1 IMC macro 510 may include a memory array and a digital operator.

The memory array may include bit cells. Bit cells connected to the same bit lines of the memory array may receive the same 1-bit weight data. The memory array may perform an AND operation between weight data (or input data) corresponding to each of the bit cells and input data (or weight data) stored in the applicable bit cell.

In the type 1 IMC macros 510, 64 bit cells included in a column may receive the same 1-bit input and perform a multiplication operation with a value stored in the bit cell. In this case, the multiplication operation may be implemented as an AND gate. 64 8-bit inputs may be streamed to the type 1 IMC macro 510 by 1 bit over 8 cycles, and operation results may be added through an adder tree. A result of the addition in the adder tree may be shifted and accumulated for the 8 cycles through a shift accumulator.

The type 2 IMC macro 520 may receive a 1-bit input for each row to perform an accumulation operation on the 1-bit input or may receive one 8-bit bit-serial input to perform a MAC operation on the 8-bit bit-serial input. When the IMC processor receives a 1-bit input to perform an accumulation operation on the 8-bit input, the IMC processor according to an example may determine whether to accumulate each row, using 16 1-bit inputs from a control unit (e.g., the control unit 460 of FIG. 4). In the type 2 IMC macro 520, 64 bit cells included in a row may receive the same 1-bit input and perform a multiplication operation on the 1-bit input with the values stored in the bit cells. In this case, the multiplication operation may be implemented as an AND gate. 16 1-bit inputs may be streamed to the type 2 IMC macro 520 over one cycle, and an operation result may be accumulated through the adder tree.

FIG. 5B illustrates an example 530 of a shift accumulator, according to one or more embodiments.

Referring to FIG. 5B, a shift accumulator 530 according to an example may be a one-dimensional shift accumulator and receive 64 inputs corresponding to the output size of each IMC macro through a MUX (e.g., the wp1 MUX 420-1 of FIG. 4). Each square shown in the shift accumulator 530 may correspond to a buffer receiving and storing the output of the IMC macro. Each input may be 16 bits when 8-bit input data and 8-bit weight data are used for computation. When 64 16-bit results are accumulated, a 22-bit output may be generated and 22 bits may be used to store an operation result of the IMC macro, without loss. For floating point and block floating point formats, only 8 bits may be used through a mantissa normalization process.

The shift accumulator 530 according to an example may receive an output result of the IMC macro for every cycle and perform a shift operation in either the left or right direction for accumulation. In addition, only one of either the shift operation or the accumulation operation may be performed in one of the left and right directions.

The shift accumulator 430 according to an example may further include a guard region in addition to an accumulation region when accumulation is performed, in order to prevent data loss during a shift operation. The size of a shift accumulator buffer may be greater than 64. The sizes of the accumulation region and the guard region may vary. For example, the sizes of the accumulation region and the guard region may be determined based on the size of a type 1 IMC macro.

Single buffers in the shift accumulator 430 according to an example may receive the same control signal in the same cycle from a control unit (e.g., the control unit 460 of FIG. 4) and perform the shift operation in the right direction or the left direction.

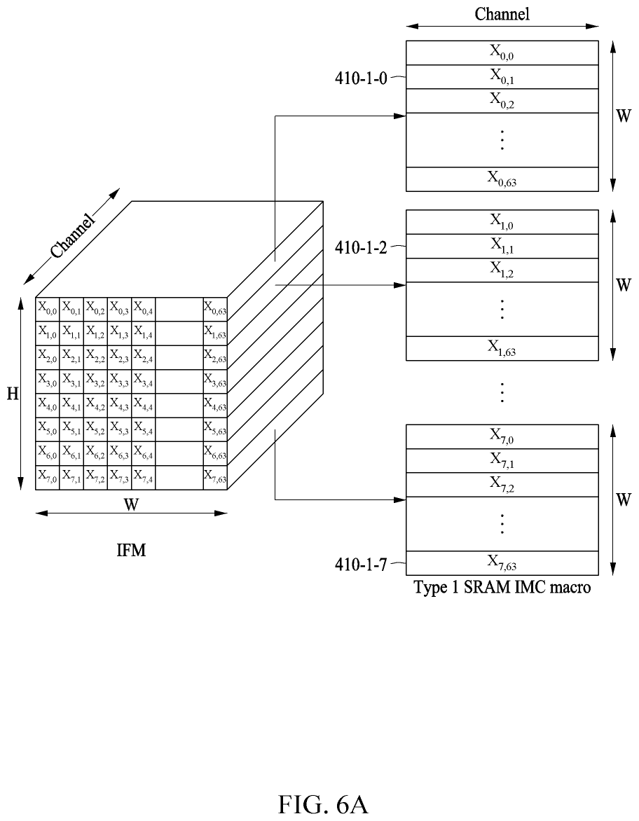

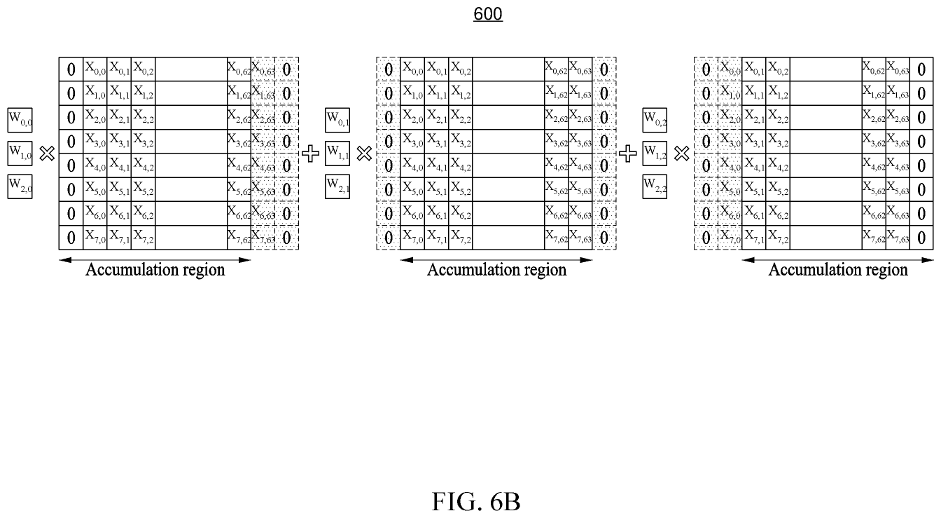

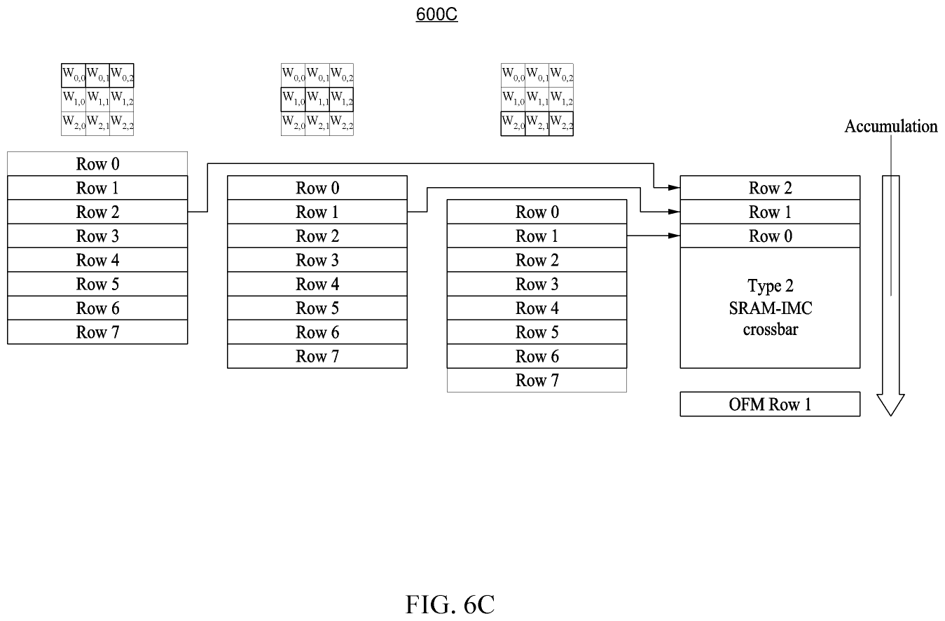

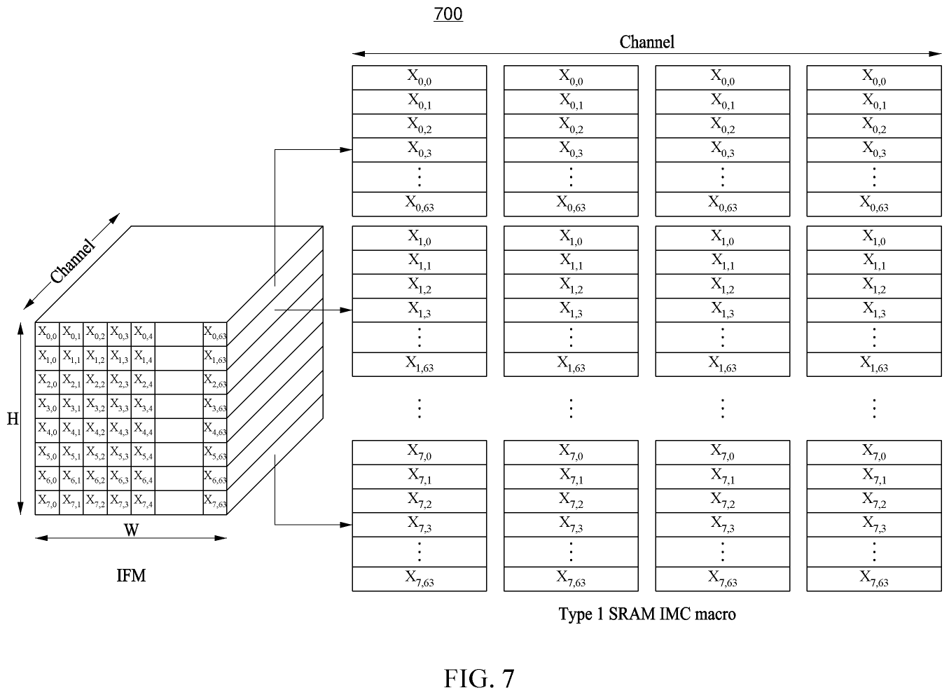

FIGS. 6A through 7 illustrate an example of a method of performing a convolution operation, according to one or more embodiments.

Referring to FIG. 6A, an IMC processor according to an example may write an output feature map, which is the output of an n^{th} layer of a neural network, in a type 1 IMC macro, which performs a convolution operation on the output feature map as an input feature map of an n+1^{th} layer of the neural network (IFM in FIG. 6A). The output feature map of the n^{th} layer may be written in the type 1 IMC macro and a channel direction is the same as an operation direction in the output feature map of the n^{th} layer. Hereinafter, it is assumed that the output feature map has a size of 8×64 and 64 channels, but examples are not limited thereto. In an example, when the input feature map has a size of 8×64 and the number of channels is 64, since the input feature map includes a total of 8×64×64 8-bit pieces of data, eight type 1 IMC macros 410-1-0, 410-1-1, . . . , and 410-1-7 having a size of 64×64 may be used to save all the data. An X_{0,0} channel having a length of 64 in the input feature map (IFM) data may be stored in a first row of the first type 1 IMC macro 410-1-0. In the input feature map data, a channel X_{0,1} may be stored in a second row of the first type 1 IMC macro 410-1-0 and a channel X_{0,64} in the input feature map data may be mapped to and stored in a 64th row of the first type 1 IMC macro 410-1-0. In the same way, a channel X_{7,64} in the input feature map data may be mapped to and stored in a 64th row of the seventh first type 1 IMC macro 410-1-7 in the memory.

A weight of a convolution operation may be streamed to type 1 IMC macros storing the input feature map stored in the type 1 IMC macro, and a dot product operation result of the input feature map and the weight may be output thereby. The output may be transferred to a shift accumulator, and operation results as many as the number of rows of a kernel (of the convolution operation) may be accumulated in an accumulation region. Hereinafter, it is assumed that the kernel has a size of 3×3 for convenience of description, but examples are not limited thereto.

Referring to the example 600 of FIG. 6B, each output vector may be shifted left and right over one cycle and accumulated by the shift accumulator. The 3×3 kernel may have weight vectors (e.g., (W_{0,0}, W_{0,1}, W_{0,2}), (W_{1,0}, W_{1,1}, W_{1,2}), and (W_{2,0}, W_{2,1}, W_{2,2})) in channel directions, respectively. In a convolution operation of the 3×3 kernel, when a MAC operation is performed between three weight vectors W_{0,0}, W_{0,1}, and W_{0,2} in a row direction and an input feature map, the output of an 8×64 size corresponding to the size of the input feature map may be obtained. The shift accumulator may shift W_{0,0} and the output of the input feature map to the left by one space/bit over one cycle and may shift W_{0,2} and the output of the input feature map to the right by one space over one cycle. Upon completion of the shift operation, when output results produced by the vectors W_{0,0}, W_{0,1}, and W_{0,2} are accumulated in the accumulation region of the shift accumulator, the IMC processor according to an example may obtain a convolution partial sum result in a row unit. When this is repeated 3 times in a column unit, a convolution operation for all of nine weight values may be completed.

Referring to the example 600C of FIG. 6C, the convolution result of the row unit (FIG. 6B) may be written in the type 2 IMC macro through the MUX 420-2 and a next output feature map may be obtained by performing accumulation in the column direction, using an adder tree of the type 2 IMC macro. In an example, convolution results Row 0, Row 1, . . . , and Row 7 of eight row units having a length of 64 by three weight vectors W_{0,0}, W_{0,1}, and W_{0,2} may be obtained through the shift accumulator. The convolution operation may be completed after a convolution result of the row unit by weight vectors in different row directions W_{1,0}, W_{1,1}, and W_{1,2}; and W_{2,0}, W_{2,1}, and W_{2,2}, and shift and accumulation in the column direction. The convolution result of the row unit may be shifted in the column direction through MUX 420-2 and be written in the type 2 IMC macro. Only a certain row of the convolution result of the row unit written in the type 2 IMC macro may be accumulated by a one-bit input that is streamed to each row. For example, a Row2 result by the weight vector (W_{0,0}, W_{0,1}, and W_{0,2}), a Row1 result by the weight vector (W_{1,0}, W_{1,1}, and W_{1,2}), and a Row0 result by the weight vector (W_{0,0}, W_{0,1}, and W_{0,2}) may be written in each row of the type 2 IMC macro, and a 1-bit input corresponding to 1 may be streamed only to a written row through the control unit 460, so that operation results of the row unit may be accumulated through the adder tree.

The computed output feature map may be written in the type 1 IMC macro in the same manner as described above and may become an input feature map of a next layer to perform a convolution operation. Accordingly, the IMC processor according to an example may perform an efficient convolution operation without additional data movement.

Referring to the example 700 of FIG. 7, an IMC processor according to an example may also perform a convolution operation having more channels. For example, when it is assumed that an input feature map has a size of 256 channels, the 256 channels may be written in four type 1 IMC macros; 64 of the channels for each.

The IMC processor according to an example may stream a weight to the type 1 IMC macro, in which the input feature map is stored and thus perform a dot product operation. A result computed in each of the type 1 IMC macros may be accumulated in a row unit through a shift accumulator. Since a total number of channels are divided into four and written in the IMC macros, there may be four partial sums in the row unit, which is four times the number partial sums in the case with an input feature map having a size of 64 channels. In the IMC processor, since a type 2 IMC macro has 16 rows, 12 partial sums may be written and accumulated in rows, respectively. Accordingly, the IMC processor may perform a convolution operation by writing and accumulating the computed partial sums in the row unit, in the type 2 IMC macro. In general, the type 1 IMC macro having a size of 64×64 may perform a dot product operation with respect to a channel direction of a size of 64, but the IMC processor according to an example may perform a convolution operation even for the case having a large number of channels.

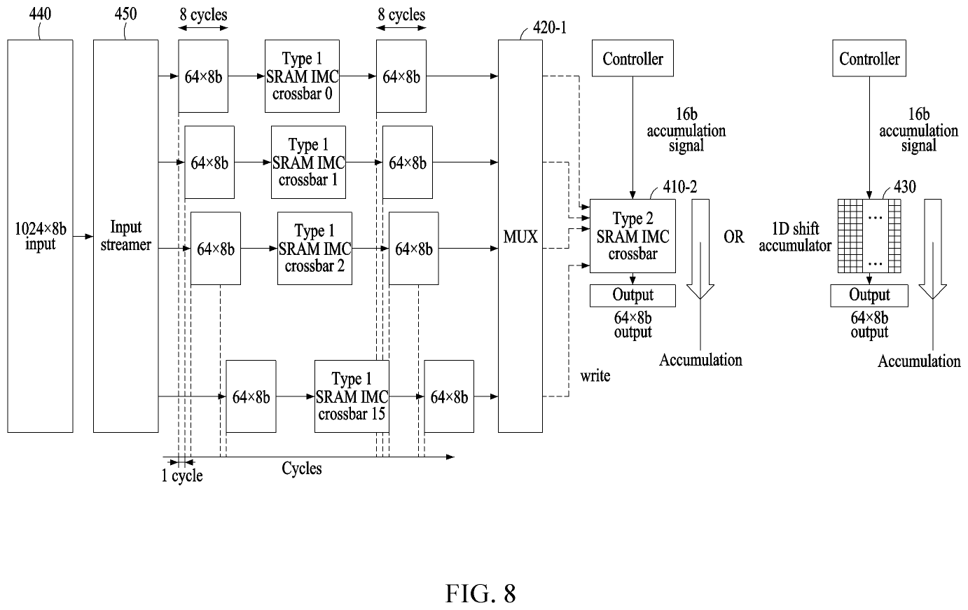

FIG. 8 illustrates an example of a method of performing a linear operation between input data and a weight, according to one or more embodiments.

Referring to FIG. 8, illustrated is a process of performing a linear operation by IMC macros sharing an input streamer 450 and a shift accumulator 430.

The input streamer 450 according to an example may read an input from memory device(s) 440 and stream the input to a type 1 IMC macro or a type 2 IMC macro (the input streamer 450 may have connections to the type 2 IMC macros in similar fashion as its connections to the type 1 IMC macros).

For example, when an input having a size of 1×64 (including 8-bit data) is streamed to the type 1 IMC macro having a size of 64×64, an IMC processor according to an example may read 64-bit data and stream the data to the type 1 IMC macro over eight cycles. An output generated for each cycle may be accumulated through an adder tree, and the IMC processor according to an example may output a final output vector having a size of 1×64.

N type 1 IMC macros may simultaneously perform computations and the input streamer 450 may stream an input to each of the type 1 IMC macros simultaneously (or at a delayed time by as much as a certain cycle). The delay between inputs may vary depending on the bandwidth of a system or an operation speed of a previous layer.

One type 1 IMC macro may compute a final output for an 8-bit input over 8 cycles. In the case of N=16, outputs of 16 type 1 IMC macros may be output simultaneously (or delayed by as much as a specific cycle), and each generated output may be written in the type 2 IMC macro. In this case, the outputs generated through the adder tree in the type 1 IMC macros may have a precision of 8 bits or more. For floating point and block floating point formats, a mantissa normalization process may be required to write 8-bit data in the type 2 IMC macro. A mantissa of eight bits or more that is changed to 8-bit data by performing the mantissa normalization process may be written in the type 2 IMC macro.

When the IMC processor according to an example performs accumulation by streaming a 1×16 vector composed of or including 1 bit as an input after 16 outputs are all written in the type 2 IMC macro, the IMC processor may obtain an output of 1×64. In general, one type 1 IMC macro having a size of 64×64 may perform a dot product operation of a size of 64, but, in the case of N=16, the IMC processor according to an example may perform a dot product operation of a size of 1024. Accumulation may be performed by the shift accumulator 430 instead of the type 2 IMC macro, and when both components are used, a dot product operation of a greater size may be performed without an additional buffer.

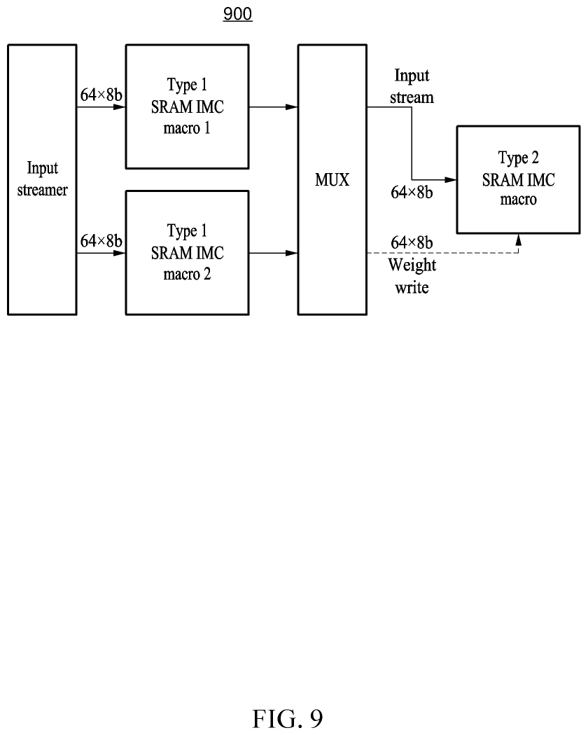

FIG. 9 illustrates an example method 900 of performing a MAC operation between an input feature map and a weight, according to one or more embodiments.

For a MAC operation between feature maps, one feature map may become an input and the other may become a weight. A feature map generated during the MAC operation may need to be stored in an IMC macro and the other may need to be streamed. In an existing IMC macro structure, a difference between a read/write direction and an operation direction has led to a restriction that a weight needs to be written in the IMC macro and an input needs to be streamed. Therefore, when the feature map of an input position is generated first, an order of an operation may need to be changed by storing the generated feature map by placing an intermediate buffer or by stalling the operation.

IMC processors according to embodiments described herein may use the type 1 IMC macro, in which the read/write direction is the same as the operation direction, and the type 2 IMC macro, in which the read/write direction is different from the operation direction, thus performing the operation without intermediate buffering or a related operation suspension.

Referring to FIG. 9, an output vector generated for each cycle may be accumulated through the adder tree and become an output feature map having a size of 1×64. Hereinafter, it is assumed that the output feature map generated by a first type 1 IMC macro be input to a next operation, and an output feature map generated by a second type 1 IMC macro becomes the weight of the next operation. A linear operation between feature maps may be performed by writing/storing the output of the second type 1 IMC macro in the type 2 IMC macro and also streaming an input to the type 2 IMC macro.

The output generated through the adder tree in the second type 1 IMC macro may have a precision of 8 bits or more and may be written in the type 2 IMC macro through a mantissa normalization process for floating point and block floating point formats. When the IMC processor streams the output of the first type 1 IMC macro after the weight is written, an efficient dataflow may be implemented since an operation may be performed without the intermediate buffer and operation suspension.

The computing apparatuses, the electronic devices, the processors, the memories, the displays, the information output system and hardware, the storage devices, and other apparatuses, devices, units, modules, and components described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An in memory computing (IMC) processor comprising:
a static random access memory (SRAM) IMC device comprising type 1 IMC macros in which a direction of writing data therein is the same as an operation direction of performing a multiply and accumulate (MAC) operation in the type 1 IMC macros, and
type 2 IMC macros in which a direction of writing data therein is different from the operation direction in the type 1 IMC macros,
wherein the SRAM IMC device is configured to use the type 1 IMC macros and the type 2 IMC macros to perform a multiply and accumulation (MAC) operation between an input feature map and a weight; and
a shift accumulator configured to perform a shift operation on an output of the SRAM IMC device and accumulate a result of the shift operation.

2. The IMC processor of claim 1, wherein
an output end of a type 1 IMC macro is connected, via the shift accumulator, with an input end of a type 2 IMC macro, and
an output end of the type 2 IMC macro is connected with an input end of the type 1 IMC macro.

3. The IMC processor of claim 1, wherein each of the type 2 IMC macros is configured to perform an accumulation operation according to the operation direction of the type 2 IMC macros by receiving one bit according to the direction of the writing of the type 2 IMC macros.

4. The IMC processor of claim 1, wherein each of the type 2 IMC macros is configured to perform their MAC operation by receiving bits according to the direction of writing of the type 2 IMC macros.

5. The IMC processor of claim 1, wherein the SRAM IMC device is configured to perform the MAC operation between the input feature map and the weight by storing the input feature map in a type 1 IMC macro while the weight is streamed into the type 1 IMC macro.

6. The IMC processor of claim 5, wherein the shift accumulator is configured to perform a first-direction partial sum operation by performing a shift operation on a MAC operation result of each of the type 1 IMC macros and by accumulating the result of the shift operation.

7. The IMC processor of claim 6, wherein the SRAM IMC device is further configured to accumulate a result of the first-direction partial sum operation using the type 2 IMC macros.

8. The IMC processor of claim 1, wherein the shift accumulator comprises a buffer, wherein the buffer comprises:
a first region storing or accumulating a MAC operation result corresponding to the type 1 IMC macros; and
a second region for preventing data loss arising from the shift operation, and wherein a size of the first region and a size of the second region are determined based on a size of the type 1 IMC macros.

9. The IMC processor of claim 1, wherein the shift accumulator is configured to be capable of performing the shift operation on a MAC operation result in a left direction and in a right direction, and is configured to accumulate the result of the shift operation.

10. The IMC processor of claim 1, wherein the MAC operation comprises a linear operation or a convolution operation.

11. The IMC processor of claim 1, wherein the IMC processor is integrated into either a mobile device, a mobile computing device, a mobile phone, a smartphone, a personal digital assistant, a fixed location terminal, a tablet computer, a computer, a wearable device, a laptop computer, a server, a music player, a video player, an entertainment unit, a navigation device, a communication device, an Internet of Things (IoT) device, a global positioning system (GPS) device, a television, a tuner, an automobile, an automotive part, an avionics system, a drone, a multi-copter, an electric vertical takeoff and landing (eVTOL) aircraft, or a medical device.

12. The IMC processor of claim 1, wherein the shift accumulator is configured to perform an accumulation operation according to the operation direction, with output vectors corresponding to the type 1 IMC macros, respectively, streamed.

13. A static random access memory (SRAM) in memory computing (IMC) device comprising:
type 1 IMC macros, in which a write direction of data is the same as an operation direction, and
type 2 IMC macros, in which a write direction of data is different from the operation direction, and
wherein the SRAM IMC device is configured to perform a multiply and accumulation (MAC) operation between an input feature map and a weight.

14. The SRAM IMC device of claim 13, wherein either the input feature map or the weight is stored in the IMC macros, and whichever of the two is not written is instead streamed to the IMC macros.

15. The SRAM IMC device of claim 13, further comprising an input streamer configured to delay a weight map corresponding to each of the type 1 IMC macros by as much as a unit cycle and stream the delayed weight map to an applicable one of the type 1 IMC macros.

16. The SRAM IMC device of claim 13, wherein the type 2 IMC macros are configured to perform an accumulation operation according to the operation direction, with output vectors corresponding to the type 1 IMC macros, respectively, streamed.

17. A method of operating an in memory computing (IMC) processor comprising:
performing a multiply and accumulation (MAC) operation between an input feature map and a weight in any one of type 1 IMC macros of the IMC processor, in which a write direction of data is the same as an operation direction of the MAC operation;
performing a first-direction partial sum operation by performing a shift operation on a MAC operation result of each of the type 1 IMC macros and accumulating a result of the shift operation; and
accumulating a result of the first-direction partial sum operation, using type 2 IMC macros of the IMC processor, in which the write direction of the data is different from a direction of the operation result.

18. A non-transitory computer-readable storage medium storing instructions that, when executed by a processor, cause the processor to perform the operating method of claim 17.
